(19) United States
(12) Patent Application Publication
(10) Pub. No.: US 2013/0078797 A1
(43) Pub. Date: Mar. 28, 2013

(54) METHOD FOR MANUFACTURING A COPPER-DIFFUSION BARRIER LAYER USED IN NANO INTEGRATED CIRCUIT

(71) Applicants: Qingqing Sun, Shanghai (CN); Lin Chen, Shanghai (CN); Wen Yang, Shanghai (CN); Pengfei Wang, Shanghai (CN); Wei Zhang, Shanghai (CN)

(72) Inventors: Qingqing Sun, Shanghai (CN); Lin Chen, Shanghai (CN); Wen Yang, Shanghai (CN); Pengfei Wang, Shanghai (CN); Wei Zhang, Shanghai (CN)

(73) Assignee: Fudan University, Shanghai (CN)

(21) Appl. No.: 13/528,363

(22) Filed: Jun. 20, 2012

(30) Foreign Application Priority Data
Sep. 23, 2011 (CN) 201110285348.6

(51) Int. Cl. H01L 21/768

(52) U.S. Cl. 438/627; 257/E21.584

(57) ABSTRACT

The present invention belongs to the technical field of integrated semiconductor circuits, and relates to a method for manufacturing a copper-diffusion barrier layer. In the present invention, a proper reaction precursor has been selected and the atomic layer deposition (ALD) technology has been adopted to develop Co or Ru on a TaN layer to obtain a diffusion barrier layer used in the interconnection for process nodes no more than 32 nm, which overcomes the insufficiency of the PVD deposition Ta/TaN double-layer structure as the copper-diffusion barrier layer in step coverage and conformity, and also effectively solves various serious problems in the Cu/low-k dual damascene process, such as the generation of voids in grooves and through-holes, and electromigration stability.

This application claims benefit of Serial No. 201110285348.6, filed 23 Sep. 2011 in China and which application is incorporated herein by reference. To the extent appropriate, a claim of priority is made to the above disclosed application.

### BACKGROUND OF THE INVENTION

1. Technical Field

The present invention belongs to the technical field of integrated semiconductor circuits, and relates to a new barrier layer material capable of preventing copper-diffusion and a preparation method thereof

2. Description of Related Art

In modern copper interconnection technology of integrated circuits, the Ta/TaN double-layer structure is deposited in the etched through-hole as the copper-diffusion barrier layer, and then a thick copper seed crystal layer is deposited to obtain a good electroplate copper layer. An effective barrier layer cannot only prevent copper-diffusion from entering the dielectric layer, but also improve the adhesion between the barrier layer and dielectric layer. As we all know, in the 0.13 μm technology node, the Ta/TaN double-layer barrier layer has been successfully applied in industrial copper interconnection technology. However, with the minimum characteristic size of integrated circuit being gradually reduced to 32 nm or less, this structure will face various challenges. Along significant increase of the height-width ratio of groove and through-holes, step coverage of the diffusion barrier layer and seed crystal copper layer sputtered by the physical vapor deposition (PVD) method has declined, which may cause voids in grooves and through-holes. Therefore, an ultra-thin diffusion barrier layer directly electroplated with copper was adopted, in this way to not only simplify the process, but also alleviate various problems caused by diffusion barrier layers and copper seed crystal layers due to poor step coverage.

Atomic layer deposition is a deposition method realized by using a surface saturated reaction on the substrate treated through bioactive surface treatment, which is insensitive to temperature and reactant flux. Atomic layer deposition has similar features with common chemical deposition, but in the atomic layer deposition process, chemical reaction of the new layer of atomic film is directly related to the previous layer; this method only deposits one atomic layer in each reaction, so film thickness can be accurately controlled through control of the number of reaction cycles. Compared with the traditional deposition process, the atomic layer deposition method has significant advantages in the aspects of film evenness, step coverage rate and thickness control, which also complies with the industrial development trend of lower budgets. However, the development process of the atomic layer deposition needs to satisfy the requirements of its absorption reaction, and selection of appropriate reaction sources and design of proper development process parameters as deposition of the barrier layer materials is critical.

### BRIEF SUMMARY OF THE INVENTION

The present invention aims at providing an ultra-thin diffusion barrier material which can be directly electroplated with copper, in this way effectively addressing the generation of voids in grooves and through-holes as well as serious problems caused by diffusion barrier layers and copper seed crystal layers due to poor step coverage in the Cu/Low-k dual damascene process.

To realize the objective of the invention above, a method for manufacturing a copper-diffusion barrier layer is proposed, comprising the following steps:
form interconnected through-holes on the first metal interconnection layer;
then, form a first metal film layer;
adopt the atomic layer deposition (ALD) technology to form a second metal film layer on the first metal film layer;
finally, form a copper interconnection structure.

Wherein, the atomic layer deposition process of the second metal film layer is:
put a base plate into an atomic layer deposition reaction chamber, and heat the reaction chamber to the process temperature;
introduce the metallorganic precursor of the second layer of metal;
introduce inert gas such as nitrogen, argon or helium gas to bring out the residual metallorganic precursors;
introduce oxidants such as ammonia or oxygen vapor;
introduce inert gas such as nitrogen, argon or helium gas once again to bring out the residual oxidant vapor;
repeat Steps—until the required film thickness has been realized;
introduce reducing gas such as hydrogen or methane to obtain a required metal film.

Further, the first layer of metal is TaN. The second layer of metal is Co or Ru.

Furthermore, when the second layer of metal is Co, the metallorganic precursor adopted includes but not limited to Co(C₅H₇O₂)₂; when the second layer of metal is Ru, the metallorganic precursor adopted includes but not limited to CpRu(CO)₂Et.

The copper-diffusion barrier layer material and its preparation method proposed in the present invention have the following advantages:
proper reaction precursors have been selected and the atomic layer deposition (ALD) technology has been adopted to develop Co or Ru on the TaN layer to obtain a diffusion barrier layer used in the interconnection for process nodes of no more than 32 nm, which has overcome the insufficiency of the PVD deposition Ta/TaN double-layer structure as the copper-diffusion barrier layer in step coverage and shape preserving, and also effectively solved various serious problems in the Cu/Low-k dual damascene process, such as generation of voids in grooves and through-holes, and electromigration stability.

Compared with the Ta/TaN barrier layer structure, the Co/Cu and Ru/Cu structure has a higher adhesion than the Ta/Cu structure, which makes it possible to directly use Co and Ru as the electroplate seed crystal layer.

### BRIEF DESCRIPTION OF THE SEVERAL VIEWS OF THE DRAWINGS

FIG. 1 is the process flow diagram of using the atomic layer deposition (ALD) technology to prepare various metal films such as Co or Ru in the present invention.

FIGS. 2˜6 are the process flow diagrams of an embodiment of manufacturing copper-diffusion barrier layer provided by the present invention.

### DETAILED DESCRIPTION OF THE INVENTION

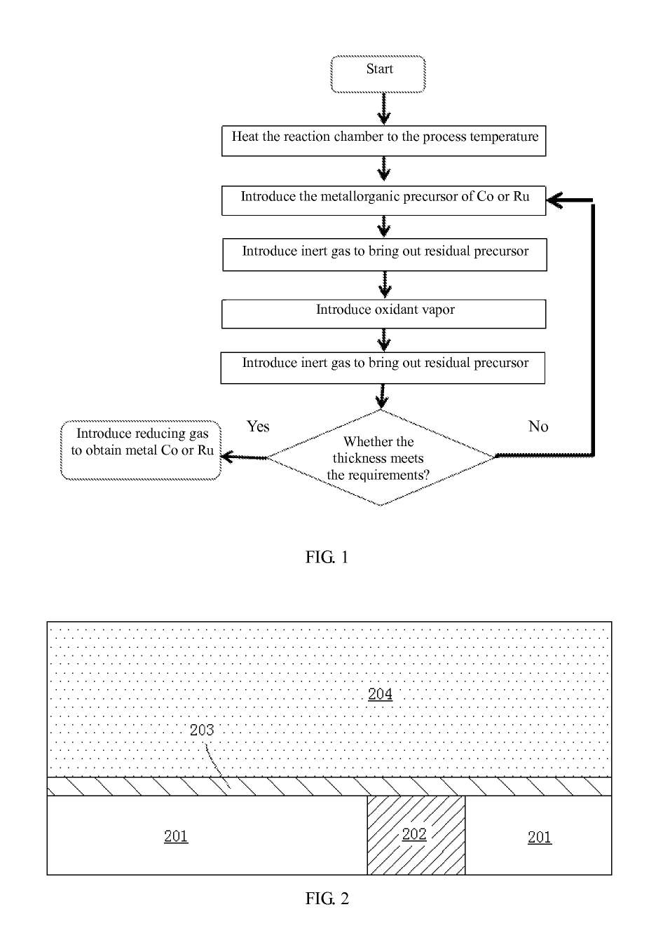

FIG. 1 is the process flow diagram using the atomic layer deposition (ALD) technology to prepare various metal films such as Co or Ru. The specific process of an embodiment according to this method to prepare Co film consists of:

1. Put a base plate of TaN diffusion barrier layer prepared into an ALD reaction chamber, heat the ALD reaction chamber to 200 required by reaction, and maintain this temperature during the whole development of ALD. Before film development, heat the reaction precursor to the set temperature, and maintain this temperature during the whole development of ALD. Before the first pulse in the pulse cycle, enhance the pressure in the reaction chamber to 2 torr required by the reaction, and maintain this pressure during the whole process.

2. Use inert gas (such as nitrogen) as the carrier gas to introduce volatilized gas during heating of Co(C₅H₇O₂)₂ into the reaction chamber, with the pulse time of 0.5 second.

3. Introduce inert gas such as argon to remove un-reacted Co(C₅H₇O₂)₂ gas and by-products from the reaction chamber, with the pulse time of 2-15 seconds.

4. Introduce oxidant vapor such as ammonia, with a pulse time of 1-2 seconds.

5. Introduce inert gas such as argon once again to remove un-reacted oxidant vapors and by-products from the reaction chamber.

6. Repeat step 2-5 until required film thickness has been realized.

7. Introduce reducing gas to the ALD reaction chamber, such as the mixed gas of H₂ and Arₑ, wherein the concentration of H₂ is 20%, and after 20 minutes, remove possible residual oxygen from the surface.

The copper-diffusion barrier layer material and the preparation method thereof proposed in the present invention applies to copper interconnection technology in various semiconductor integrated circuits. The following is an embodiment of the preparation of Co/TaN double-layer diffusion barrier layer in 22 nm process provided by the present invention.

In the drawings, the thickness of layers and regions are either zoomed in or out for the convenience of description, so it shall not be considered as the true size. Although the drawings cannot accurately reflect the true size of the devices, they still reflect the relative position among regions and composition structures, especially the up-down and adjacent relations.

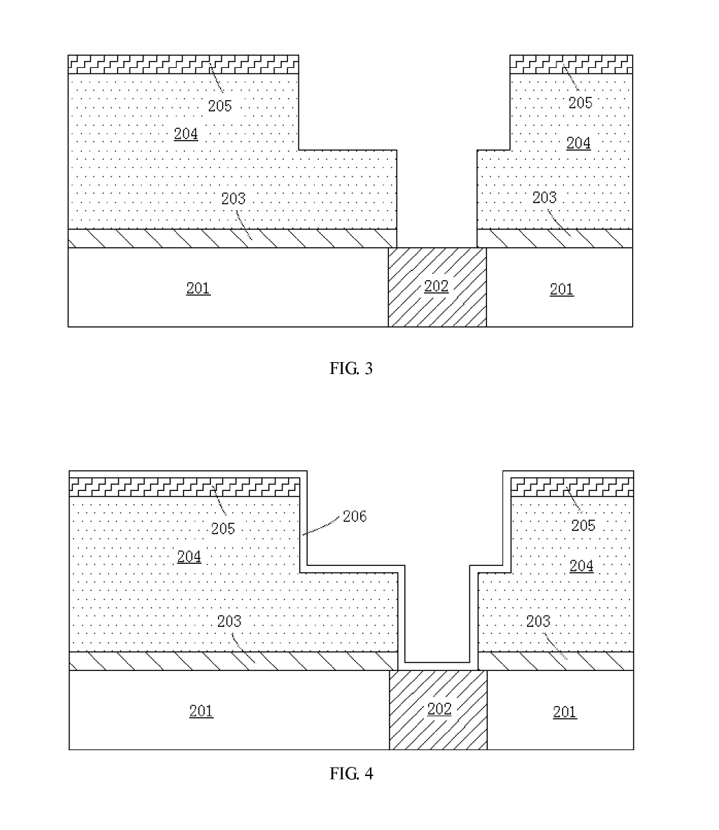

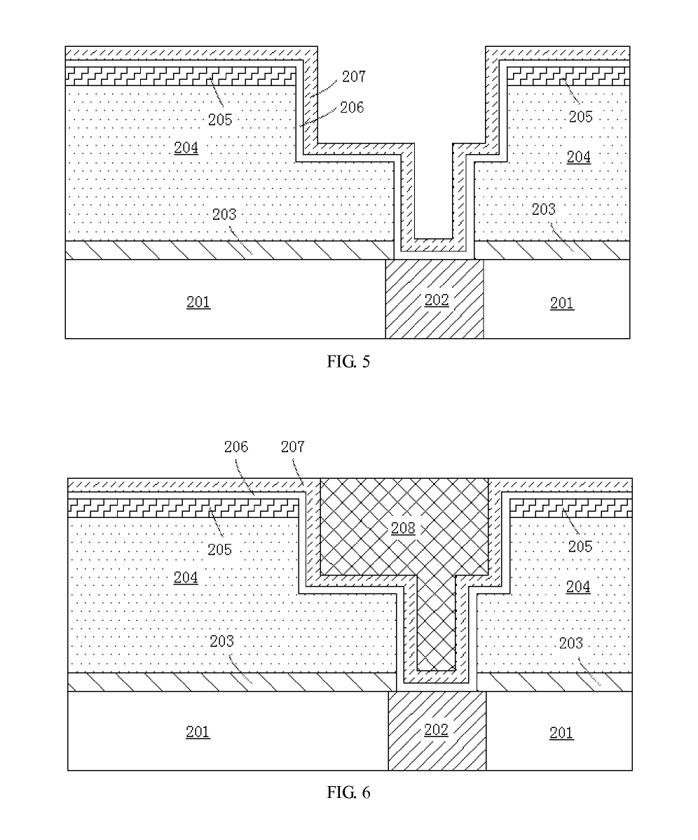

First of all, on the base plate of the first metal interconnection layer formed, prepare an etching barrier layer and a Low-k dielectric layer in turn by means of the chemical vapor deposition (CVD) process. As shown in FIG. 2, the 201 indicated is an insulating dielectric, such as silica; the 202 is a first metal interconnection layer; the 203 is an etching barrier layer, such as silicon nitride; the 204 is a Low-k dielectric layer.

Next, deposit an etching barrier layer 205 on the Low-k dielectric layer 204, such as silicon nitride, and then, form interconnected through-holes according to dual damascene, including photoetching and etching, as shown in FIG. 3. Afterwards, prepare a TaN diffusion barrier layer 206 through reaction ions sputtering or atomic layer deposition (ALD) method, as shown in FIG. 4.

Then, put the base plate with the TaN diffusion barrier layer prepared into the atomic layer deposition device, and develop a layer of Co film 207 on the TaN diffusion barrier layer 206 to form a copper-diffusion barrier layer with Co/TaN double-layer structure according to the atomic layer deposition method of Co film provided by the present invention, as shown in FIG. 5.

At last, form a layer of metal copper 208 by means of electroplate technology, and form a copper interconnection structure by means of chemical and mechanical polishing technology, as shown in FIG. 6.

As described above, without deviating from the spirit and scope of the present invention, there may be many significantly different embodiments. It shall be understood that the present invention is not limited to the specific embodiments described in the Specification except those limited by the Claims herein.

What is claimed is:

1. A method for manufacturing a copper-diffusion barrier layer, characterized in that it is comprised of the following steps:
form interconnected through-holes on a first metal interconnection layer;
form a first metal film;
adopt the atomic layer deposition (ALD) technology to form a second metal film;
form a copper interconnection structure.
wherein, the atomic layer deposition process of the second metal film is:
\textcircled{1} put a base plate into an atomic layer deposition reaction chamber, and heat the reaction chamber to the process temperature;
\textcircled{2} introduce the metallorganic precursor of the second layer of metal;
\textcircled{3} introduce inert gas to bring out the residual metallorganic precursor;
\textcircled{4} introduce an oxidant vapor;
\textcircled{5} introduce the inert gas once again to bring out the residual oxidant vapor;
\textcircled{6} repeat Steps \textcircled{2}-\textcircled{5} until achieving the required film thickness;
\textcircled{7} introduce a reducing gas to obtain the required metal film.

2. The method for manufacturing a copper-diffusion barrier layer according to claim 1, wherein the first layer of metal is TaN.

3. The method for manufacturing a copper-diffusion barrier layer according to claim 1, wherein the second layer of metal is Co or Ru.

4. The method for manufacturing a copper-diffusion barrier layer according to claim 3, wherein the second layer of the metal is Co, and its metallorganic precursor is Co(C₅H₇O₂)₂.

5. The method for manufacturing a copper-diffusion barrier layer according to claim 3, wherein the second layer of metal is Ru, wherein its metallorganic precursor is CpRu(CO)₂Et.

6. The method for manufacturing a copper-diffusion barrier layer according to claim 1, wherein the inert gas is nitrogen, argon or helium gas.

7. The method for manufacturing a copper-diffusion barrier layer according to claim 1, wherein the oxidant is ammonia or oxygen.

8. The method for manufacturing a copper-diffusion barrier layer according to claim 1, wherein the reducing gas is hydrogen or methane.
